(19) United States
(12) Patent Application Publication
(10) Pub. No.: US 2025/0070023 A1
(43) Pub. Date: Feb. 27, 2025

(54) SEMICONDUCTOR DEVICE

(71) Applicant: Kioxia Corporation, Tokyo (JP)

(72) Inventors: Hisashi KATO, Yokkaichi Mie (JP); Masayoshi TAGAMI, Kuwana Mie (JP); Akira NAKAJIMA, Zama Kanagawa (JP)

(73) Assignee: Kioxia Corporation, Tokyo (JP)

(21) Appl. No.: 18/808,257

(22) Filed: Aug. 19, 2024

(30) Foreign Application Priority Data
Aug. 24, 2023 (JP) 2023-136376

(51) Int. Cl. H01L 23/528; G11C 16/04; H01L 23/00; H01L 23/522; H01L 23/532; H10B 41/10; H10B 41/27; H10B 43/10; H10B 43/27

(52) U.S. Cl. CPC H01L 23/5283; G11C 16/0483; H01L 23/5226; H01L 23/53228; H01L 23/53295; H01L 24/08; H10B 41/10; H10B 41/27; H10B 43/10; H10B 43/27; H01L 2224/08146

(57) ABSTRACT

A semiconductor device includes a first chip including a first insulating layer; a second chip bonded to the first chip and including a second insulating layer; and a pad provided around a bonded surface between the first chip and the second chip. The pad includes a first metal layer including a first metal, a second metal layer disposed between the first metal layer and the first insulating layer, and a third metal layer disposed between the first metal layer and the second insulating layer. At least one of the second metal layer or the third metal layer include a second metal having oxidation energy lower than oxidation energy of the first metal. The first metal layer further includes the second metal.

### CROSS-REFERENCE TO RELATED APPLICATION

This application is based upon and claims the benefit of priority from Japanese Patent Application No. 2023-136376, filed Aug. 24, 2023, the entire contents of which are incorporated herein by reference.

### FIELD

Embodiments described herein relate generally to a semiconductor device.

### BACKGROUND

In some semiconductor devices, different elements are formed on different substrates, which are bonded to each other to be manufactured. Pads electrically connected to each element are formed on bonded surfaces of the substrates. By bonding the substrates, the pads are also joined to each other, and the different elements are also electrically connected to each other. However, when the pads are joined to each other, the electrical conduction between the pads may be inhibited by an oxide layer formed on the surfaces of the pads by natural oxidation or the like.

### DESCRIPTION OF THE DRAWINGS

FIG. 1 is a block diagram of a semiconductor memory device according to an embodiment.

FIG. 2 is an equivalent circuit diagram showing an example of a configuration of a memory cell array provided in the semiconductor memory device according to the embodiment.

FIG. 3 is a cross-sectional view showing a schematic configuration example of the semiconductor memory device according to the embodiment.

FIGS. 4A to 4E are views showing an example of a configuration of the semiconductor memory device according to the embodiment.

FIGS. 5A to 5E are views sequentially showing a part of a procedure of a method for manufacturing the semiconductor memory device according to the embodiment.

FIGS. 6A to 6C are views sequentially showing a part of the procedure of the method for manufacturing the semiconductor memory device according to the embodiment.

FIGS. 7A to 7C are views sequentially showing a part of the procedure of the method for manufacturing the semiconductor memory device according to the embodiment.

FIGS. 8A to 8H are views sequentially showing a part of the procedure of the method for manufacturing the semiconductor memory device according to the embodiment.

FIGS. 9A to 9F are views sequentially showing a part of the procedure of the method for manufacturing the semiconductor memory device according to the embodiment.

FIGS. 10A and 10B are views sequentially showing a part of the procedure of the method for manufacturing the semiconductor memory device according to the embodiment.

FIGS. 11A to 11F are views showing a part of the procedure of the method for manufacturing the semiconductor memory device according to Modification Example 1 of the embodiment.

FIGS. 12A to 12C are cross-sectional views of a joining portion of an insulating layer of the semiconductor memory device according to Modification Example 2 of the embodiment.

### DETAILED DESCRIPTION

In general, according to one embodiment, a semiconductor device includes a first chip including a first insulating layer; a second chip bonded to the first chip and including a second insulating layer; and a pad provided around a bonded surface between the first chip and the second chip. The pad includes a first metal layer including a first metal, a second metal layer disposed between the first metal layer and the first insulating layer, and a third metal layer disposed between the first metal layer and the second insulating layer. At least one of the second metal layer or the third metal layer include a second metal having oxidation energy lower than oxidation energy of the first metal. The first metal layer further includes the second metal.

Hereinafter, embodiments of the present disclosure will be described in detail with reference to the drawings. Further, the present disclosure is not limited to the following embodiment. Elements in the following embodiments include those that may be easily assumed by those skilled in the art or those that are substantially the same.

### Configuration Example of Semiconductor Memory Device

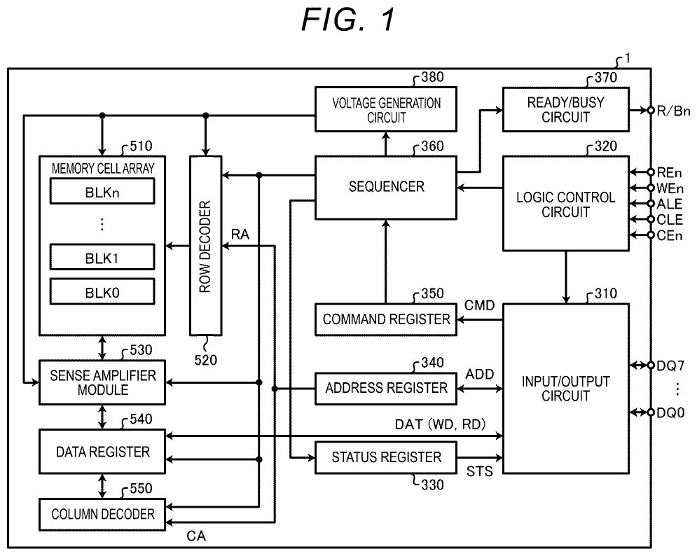

FIG. 1 is a block diagram of a semiconductor memory device 1 according to an embodiment. As shown in FIG. 1, the semiconductor memory device 1 includes an input/output circuit 310, a logic control circuit 320, a status register 330, an address register 340, a command register 350, a sequencer 360, a ready/busy circuit 370, a voltage generation circuit 380, a memory cell array 510, a row decoder 520, a sense amplifier module 530, a data register 540, and a column decoder 550.

The input/output circuit 310 controls the input and output of signal DQ with an external device such as a memory controller (not shown) that controls the semiconductor memory device 1. The input/output circuit 310 includes an input circuit and an output circuit (not shown).

The input circuit transmits the data DAT such as the write data WD received from the external device to the data register 540, transmits the address ADD to the address register 340, and transmits the command CMD to the command register 350.

The output circuit transmits the status information STS received from the status register 330, the data DAT such as the read data RD received from the data register 540, and the address ADD received from the address register 340 to the external device.

The logic control circuit 320 receives, for example, a chip enable signal CEn, a command latch enable signal CLE, an address latch enable signal ALE, a write enable signal WEn, and a read enable signal REn from the external device. Further, the logic control circuit 320 controls the input/output circuit 310 and the sequencer 360 according to the received signal.

The status register 330 temporarily stores, for example, the status information STS in a write operation, a read operation, and an erasing operation of data, and notifies the external device whether the operation is successfully completed.

The address register 340 temporarily stores the address ADD received from the external device via the input/output circuit 310. Further, the address register 340 transfers the row address RA to the row decoder 520 and transfers the column address CA to the column decoder 550.

The command register 350 temporarily stores the command CMD received from the external device via the input/output circuit 310 and transfers the command CMD to the sequencer 360.

The sequencer 360 controls the operation of the semiconductor memory device 1 as a whole. More specifically, the sequencer 360 controls, for example, the status register 330, the ready/busy circuit 370, the voltage generation circuit 380, the row decoder 520, the sense amplifier module 530, the data register 540, the column decoder 550, and the like in accordance with the command CMD stored in the command register 350, and executes a write operation, a read operation, an erasing operation, and the like.

The ready/busy circuit 370 transmits the ready/busy signal R/Bn to the external device in accordance with the operation status of the sequencer 360.

The voltage generation circuit 380 generates a voltage required for a write operation, a read operation, and an erasing operation in accordance with the control of the sequencer 360, and supplies the generated voltage to, for example, the memory cell array 510, the row decoder 520, the sense amplifier module 530, and the like. The row decoder 520 and the sense amplifier module 530 apply the voltage supplied from the voltage generation circuit 380 to the memory cells in the memory cell array 510.

The memory cell array 510 includes a plurality of blocks BLK (BLK0 to BLKn). n is an integer of 2 or more. The block BLK is a set of a plurality of memory cells associated with a bit line and a word line, and is, for example, a data erasure unit. The memory cell is configured as, for example, a transistor and stores nonvolatile data.

The semiconductor memory device 1 according to the embodiment is configured as, for example, a NAND-type nonvolatile memory by providing such a memory cell.

The row decoder 520 decodes the row address RA. The row decoder 520 selects any of the blocks BLK based on the decoding result. The row decoder 520 applies the necessary voltage to the block BLK.

The sense amplifier module 530 senses data read from the memory cell array 510 during a read operation. The sense amplifier module 530 transmits the read data RD to the data register 540. During a write operation, the sense amplifier module 530 transmits the write data WD to the memory cell array 510.

The data register 540 includes a plurality of latch circuits. The latch circuit stores write data WD and read data RRD. For example, in the write operation, the data register 540 temporarily stores the write data WD received from the input/output circuit 310 and transmits the write data WD to the sense amplifier module 530. Further, for example, in the read operation, the data register 540 temporarily stores the read data RD received from the sense amplifier module 530 and transmits the read data RD to the input/output circuit 310.

The column decoder 550 decodes the column address CA, for example, during a write operation, a read operation, and an erasing operation, and selects the latch circuit in the data register 540 according to the decoding result.

Additionally, a circuit group disposed around the memory cell array 510 is also referred to as a peripheral circuit. The peripheral circuit includes at least the row decoder 520, the sense amplifier module 530, the data register 540, and the column decoder 550. The peripheral circuit may include the status register 330, the address register 340, the command register 350, and the sequencer 360, and may further include the input/output circuit 310, the logic control circuit 320, the ready/busy circuit 370, and the voltage generation circuit 380.

As described above, the semiconductor memory device 1 according to the embodiment includes the memory cell array 510 that includes a plurality of memory cells and a peripheral circuit that operates the plurality of memory cells.

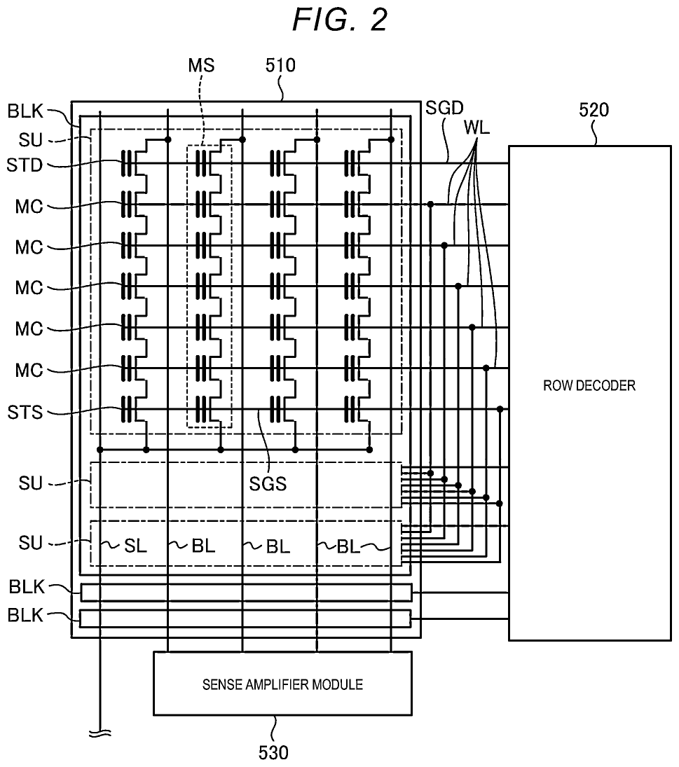

FIG. 2 is an equivalent circuit diagram showing an example of a configuration of the memory cell array 510 provided in the semiconductor memory device 1 according to the embodiment.

The memory cell array 510 includes a plurality of blocks BLK as described above. Each of the plurality of blocks BLK includes a plurality of string units SU. Each of the plurality of string units SU includes a plurality of memory strings MS. One end of each of the plurality of memory strings MS is connected to a peripheral circuit such as the sense amplifier module 530 via a bit line BL. The other end of each of the plurality of memory strings MS is connected to the peripheral circuit PC via a common source line SL.

The memory string MS includes a drain select transistor STD that is connected in series between the bit line BL and the source line SL, a plurality of memory cells MC, and a source select transistor STS. Hereinafter, the drain select transistor STD and the source select transistor STS may be simply referred to as select transistors (STD, STS).

The memory cell MC is, for example, a field effect transistor (FET) including a charge storage layer in a gate insulating layer. The threshold voltage of the memory cell MC changes in accordance with the charge quantity in the charge storage layer. By providing one or a plurality of threshold voltages, the memory cell MC may be able to store one bit or a plurality of bits of data. The word line WL is connected to each of the gate electrodes of the plurality of memory cells MC corresponding to one memory string MS. Each of these word lines WL is commonly connected to all the memory strings MS in one block BLK.

The select transistors (STD, STS) are, for example, field effect transistors. Select gate lines (SGD, SGS) are respectively connected to the gate electrodes of the select transistors (STD, STS). The drain select line SGD connected to the drain select transistor STD is provided corresponding to the string unit SU, and is commonly connected to all the memory strings MS in one string unit SU. The source select line SGS connected to the source select transistor STS is commonly connected to all of the memory strings MS in one block BLK.

One end of the word lines WL and the select gate lines (SGD, SGS) are respectively connected to a peripheral circuit such as a row decoder 520.

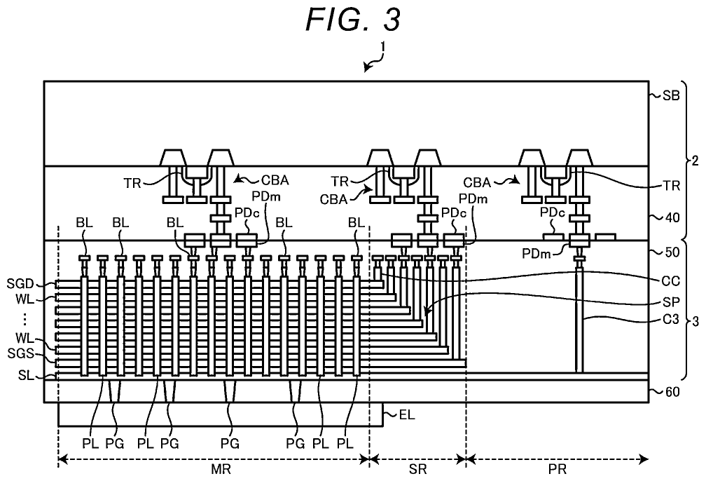

FIG. 3 is a cross-sectional view showing a configuration example of a semiconductor memory device 1 according to the embodiment. However, in FIG. 3, hatching is omitted in consideration of the visibility of the drawing.

As shown in FIG. 3, the semiconductor memory device 1 has a configuration in which the two chips 2 and 3 are joined to each other at insulating layer 40 and 50 portions provided in the chips 2 and 3, respectively. The chip 2 as the first chip includes an electrode film EL, a source line SL, a plurality of word lines WL, and select gate lines SGD and SGS in order from the lower side of the paper surface. The chip 3 as the second chip is disposed above the select gate line SGD and includes a peripheral circuit CBA provided on a semiconductor substrate SB.

The source line SL is disposed on the electrode film EL through an insulating layer 60. A plurality of the plugs PG are disposed in an insulating layer 150, and the source line SL and the electrode film EL maintain electrical conduction via the plugs PG. Thereby, the source voltage may be applied to the source line SL from the above-described voltage generation circuit 380 (refer to FIG. 1) via the electrode film EL and the plug PG.

One or more select gate lines SGS, a plurality of word lines WL, and one or more select gate lines SGD are stacked in this order on the source line SL. A memory region MR is disposed at a center portion in a direction in which the plurality of word lines WL extend, and a staircase region SR is disposed at an end portion in the direction in which the plurality of word lines WL extend.

A plurality of pillars PL penetrating the word line WL or the like in a stacking direction are disposed in the memory region MR. A plurality of memory cells MC (refer to FIG. 2) are formed at an intersection portion between the pillar PL and the word line WL. Accordingly, the semiconductor memory device 1 is configured as, for example, a three-dimensional nonvolatile memory in which memory cells MC are disposed in three dimensions in the memory region MR.

As described above, the memory region MR is an example of a physical configuration corresponding to the above-described memory cell array 510 (refer to FIG. 2). Further, the pillar PL is an example of a physical configuration corresponding to the above-described memory string MS (refer to FIG. 2) in which the memory cells MC and the like are connected in series.

In the physical configuration of the semiconductor memory device 1, the pillar PL is electrically connected to the peripheral circuit CBA via the bit line BL disposed above the pillar PL.

In the staircase region SR, a step portion SP in which the plurality of word lines WL and select gate lines SGD and SGS are processed in a stepped shape and terminated is disposed. A contacts CC connected to the word lines WL and the like of each step layer are respectively disposed in the terrace portions of each step of the step portion SP configured with the individual word lines WL and the like.

The word lines WL and the select gate lines SGD and SGS, which are stacked in multiple layers, are individually drawn out by the contacts CC. These contacts CC are used to apply a write voltage, a read voltage, and the like to the memory cells MC provided in the memory region MR at the center portion of the plurality of word lines WL, via the word lines WL at the same height position as the memory cells MC.

The plurality of word lines WL, the select gate lines SGD and SGS, the pillars PL, and the contacts CC are covered with the insulating layer 50 as the first insulating layer. The insulating layer 50 also extends to a peripheral region PR around the plurality of word lines WL and the like. The contact C3 connected to the source line SL through the insulating layer 50 is disposed in the peripheral region PR.

In addition, pads PDm as a plurality of first pads are disposed on the surface of the insulating layer 50, and the above-described pillar PL, contacts CC and C3, and the like are electrically connected to the pads PDm via vias, wirings, and the like.

The semiconductor substrate SB above the insulating layer 50 is, for example, a silicon substrate or the like. The peripheral circuit CBA such as the described-above row decoder 520 including the transistor TR and the wiring, the sense amplifier module 530 (refer to FIG. 1), and the like are disposed on the surface of the semiconductor substrate SB.

Various voltages applied from the contact CC to the memory cell MC are controlled by the peripheral circuit CBA electrically connected to the contact CC. In addition, the data read from the memory cell MC arranged in the height direction of the pillar PL is read to the sense amplifier module 530 of the peripheral circuit CBA. Thereby, the peripheral circuit CBA controls the electrical operation of the memory cell MC.

The peripheral circuit CBA is covered with the insulating layer 40 as the second insulating layer. Pads PDc as a plurality of second pads are disposed on the surface of the insulating layer 40, and the above-described transistor TR and the like are electrically connected to the pads PDc via a via, a wiring, and the like.

The semiconductor memory device 1 of the embodiment is configured to include the plurality of word lines WL, the plurality of pillars PL, the source lines SL, the contacts CC, and the like, and the peripheral circuit CBA by joining the insulating layer 40 that covers the peripheral circuit CBA and the insulating layer 50 that covers the plurality of word lines WL and the like.

These configurations are electrically connected to each other by joining the pads PDc and PDm to each other due to the joining of the insulating layers 40 and 50. That is, the pillar PL is connected to the peripheral circuit CBA via the bit line BL and the pads PDm and PDc. The word line WL and the like are connected to the peripheral circuit CBA via the contact CC, the pads PDm and PDc, and the like. The source line SL is connected to the peripheral circuit CBA via the contact C3 and the pads PDm and PDc.

The semiconductor memory device 1 configured as described above is an example of a semiconductor device including chips 2 and 3 having bonded surfaces between the insulating layer 50 and the insulating layer 40. The chips 2 and 3 are obtained by bonding substrates, on which a plurality of word lines WL, pillars PL, source lines SL, contacts CC, and the like, and a peripheral circuit CBA are respectively formed, to each other, and then individually dividing the bonded substrates.

In the present specification, the side on which the pad PDm is disposed is defined as the lower side of the semiconductor memory device 1, and the side on which the pad PDc is disposed is defined as the upper side of the semiconductor memory device 1 among the pad PDm connected to the plurality of word lines WL, pillars PL, source lines SL, the contacts CC, and the like, and the pad PDc connected to the peripheral circuit CBA.

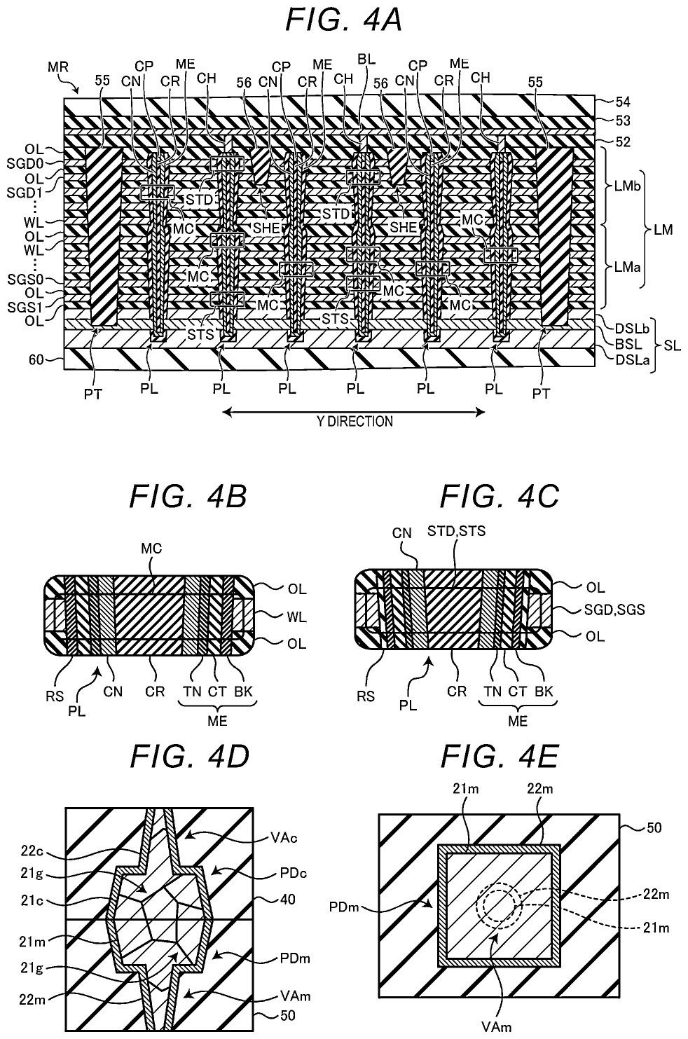

Next, a detailed configuration example of the semiconductor memory device 1 will be described with reference to FIGS. 4A to 4E. FIGS. 4A to 4E are views showing an example of a configuration of a semiconductor memory device 1 according to the embodiment.

More specifically, FIG. 4A is a sectional view along the Y direction including the memory region MR of the semiconductor memory device 1. In FIG. 4A, the structure below the insulating layer 60 and above the insulating layer 54 is omitted.

FIG. 4B is an XY cross-sectional view of the pillar PL at a height position of any word line WL. FIG. 4C is an XY cross-sectional view of the pillar PL at a height position of any select gate lines SGD and SGS.

FIG. 4D is a cross-sectional view of a joining portion of the insulating layers 40 and 50. FIG. 4E is an XY cross-sectional view of the pad PDm provided in the insulating layer 50.

In addition, in the present specification, both the X direction and the Y direction are directions along the direction of the plane of the word line WL, and the X direction and the Y direction are orthogonal to each other.

As shown in FIG. 4A, the source line SL has a multilayer structure in which, for example, a lower source line DSLa, an intermediate source line BSL, and an upper source line DSLb are stacked in this order on the insulating layer 60. The intermediate source line BSL is not disposed below the staircase region SR of the stacked body LM.

The lower source line DSLa, the intermediate source line BSL, and the upper source line DSLb are, for example, a polysilicon layer or the like. Among the above, at least the intermediate source line BSL may be a conductive polysilicon layer or the like in which impurities are diffused.

A stacked body LM is disposed on the source line SL. The stacked body LM is provided with stacked bodies LMa and LMb in which the plurality of word lines WL and a plurality of insulating layers OL are alternately stacked by one layer.

The stacked body LMa is disposed above the source line SL. A plurality of select gate lines SGS0 and SGS1 are disposed in this order from the upper layer side of the stacked body LMa in the further lower layer of the word line WL of the lowermost layer of the stacked body LMa via the insulating layer OL. The stacked body LMb is disposed on the stacked body LMa. A plurality of select gate lines SGD0 and SGD1 are disposed in this order from the upper layer side of the stacked body LMb in the further upper layer of the word line WL of the uppermost layer of the stacked body LMb via the insulating layer OL.

The number of stacked layers of the word lines WL and the select gate lines SGD and SGS as the conductive layers in the stacked body LM is predetermined. The word line WL and the select gate lines SGD and SGS are, for example, a tungsten layer, a molybdenum layer, or the like. The insulating layer OL is, for example, a silicon oxide layer.

The uppermost insulating layers OL of the stacked bodies LMa and LMb are respectively thicker than, for example, the other insulating layers OL in the stacked bodies LMa and LMb. Meanwhile, the insulating layers OL of the respective stacked bodies LMa and LMb may have substantially the same thickness. The uppermost insulating layer OL of the stacked body LMa is in contact with the word line WL of the lowermost layer of the stacked body LMb, and insulating layers 52, 53, 54, . . . are disposed in this order on the uppermost insulating layer OL of the stacked body LMb.

The insulating layers 52, 53, 54, . . . constitute a part of the above-described insulating layer 50, and the insulating layer 50 is in contact with the lower surface of the insulating layer 40 on the peripheral circuit CBA side as described above at the uppermost surface (not shown) in FIG. 4A.

The stacked body LM is also divided in the Y direction by a plurality of plate-shaped portions PT.

That is, each of the plate-shaped portions PT is arranged in the Y direction, and extends in the direction along the stacking direction and the X direction of the stacked body LM. In this way, the plate-shaped portion PT continuously extends in the stacked body LM from one end portion to the other end portion of the stacked body LM in the X direction. In addition, the plate-shaped portion PT penetrates the stacked body LM and the upper source line DSLb, and reaches the intermediate source line BSL in the memory region MR. Each of the plate-shaped portions PT is configured as an independent insulating layer 55 such as a silicon oxide layer.

In addition, the plate-shaped portion PT has, for example, a tapered shape in which the width in the Y direction is reduced from the upper end portion toward the lower end portion. Alternatively, the plate-shaped portion PT has, for example, a bowing shape in which the width in the Y direction is maximum at a predetermined position between the upper end portion and the lower end portion.

In the memory region MR, a plurality of separation layers SHE extending in the direction along the X direction through the upper layer portion of the stacked body LM are disposed between the plate-shaped portions PT adjacent to each other in the Y direction. The separation layers SHE are insulating layers 56, such as a silicon oxide layer, that penetrate the select gate lines SGD0 and SGD1 and reach the insulating layer OL immediately below the select gate line SGD1.

In other words, the separation layers SHE that penetrate the upper layer portion of the stacked body LM extend in the X direction of the memory region MR at between the adjacent plate-shaped portions PT, and thus the upper layer portion of the stacked body LM is partitioned into the above-described select gate lines SGD0 and SGD1.

The region between the plate-shaped portions PT adjacent to each other in the Y direction is an example of a physical configuration corresponding to above-described one block BLK (refer to FIG. 2). In addition, a region partitioned by the separation layer SHE into the patterns of the select gate lines SGD0 and SGD1 at between the adjacent plate-shaped portions PT is an example of a physical configuration corresponding to the above-described string unit SU (refer to FIG. 2).

The plurality of pillars PL, which penetrates the stacked body LM, the upper source line DSLb, and the intermediate source line BSL and reaches the lower source line DSLa, are disposed in the memory region MR in a dispersion manner.

The plurality of pillars PL are disposed, for example, in a zigzag shape when viewed in the stacking direction of the stacked body LM. Each of the pillars PL has a shape such as a circular shape, an elliptical shape, or an oblong shape (oval shape) as a cross-sectional shape in a direction along a layer direction of the stacked body LM, that is, the direction along the XY plane.

In addition, the pillars PL each have a tapered shape in which the diameter and the cross-sectional area are reduced from the upper layer side toward the lower layer side in a portion penetrating the stacked body LMa and a portion penetrating the stacked body LMb. Alternatively, the pillars PL each have, for example, a bowing shape in which the diameter and the cross-sectional area are maximized at a predetermined position between the upper layer side and the lower layer side in the portion penetrating the stacked body LMa and the portion penetrating the stacked body LMb.

Each of the plurality of pillars PL has a memory layer ME extending in the stacked body LM in the stacking direction, a channel layer CN that penetrates the stacked body LM and that is connected to the intermediate source line BSL, a cap layer CP at an upper end portion of the pillar PL, and a core layer CR serving as a core material of the pillar PL.

As shown in FIGS. 4B and 4C, the memory layer ME has a multilayer structure in which a block insulating layer BK, a charge storage layer CT, and a tunnel insulating layer TN are stacked in this order from an outer peripheral side of the pillar PL. More specifically, the memory layer ME is disposed on a side surface of the pillar PL excluding a depth position of the intermediate source line BSL. In addition, the memory layer ME is also disposed on a bottom surface of the pillar PL reaching a depth of the lower source line DSLa.

The channel layer CN penetrates the stacked body LM, the upper source line DSLb, and the intermediate source line BSL inside the memory layer ME, and reaches the depth of the lower source line DSLa. More specifically, the channel layer CN is disposed on the side surface and the bottom surface of the pillar PL via the memory layer ME. Meanwhile, a part of the channel layer CN is in contact with the intermediate source line BSL on a side surface, and thus is electrically connected to the source line SL provided with the intermediate source line BSL. The core layer CR further fills the channel layer CN.

In addition, each of the plurality of pillars PL has the cap layer CP connected to the channel layer CN at an upper end portion. The cap layer CP is connected to the bit line BL disposed in the insulating layer 53 via the plug CH disposed in the insulating layer 52. The bit line BL extends above the stacked body LM in a direction, for example, along the Y direction so as to intersect the drawing-out direction of the word line WL.

In FIG. 4A, the plug CH is connected only to one pillar PL in each of the compartments separated by the separation layer SHE. The rest of pillars PL are connected to the other bit lines BL extending in the direction along the Y direction in parallel to the bit line BL shown in FIG. 4A at a position different from the cross section shown in FIG. 4A via the plug CH (not shown in FIG. 4A).

The block insulating layer BK and the tunnel insulating layer TN of the memory layer ME and the core layer CR are, for example, silicon oxide layers or the like. The charge storage layer CT of the memory layer ME is, for example, a silicon nitride layer or the like. The channel layer CN and the cap layer CP are, for example, semiconductor layers such as polysilicon layers or amorphous silicon layers.

As shown in FIG. 4B, according to the above configuration, the memory cell MC is formed in each of the portions of the side surface of the pillar PL facing the individual word lines WL. A predetermined voltage is applied from the word line WL to write and read data to and from the memory cell MC.

As shown in FIG. 4C, according to the above configuration, the select gate STD is formed in each of the portions in which the side surface of the pillar PL faces the select gate line SGD0 and SGD1 disposed in the upper layer of the word line WL. In addition, the select gate STS is formed in each of the portions in which the side surface of the pillar PL faces the select gate lines SGS0 and SGS1 disposed in the lower layer of the word line WL.

By applying a predetermined voltage from each of the select gate lines SGD and SGS, the select gates STD and STS are turned on or off, and the memory cell MC of the pillar PL to which the select gates STD and STS belong may be set to be in a selected state or an unselected state.

Since the plurality of pillars PL are disposed in a dispersion manner, as will be described later, the stacked body is supported in the memory region MR when the stacked body LM is formed from the stacked body in which the sacrificial layer and the insulating layer are stacked. On the other hand, a plurality of columnar portions (not shown) instead of the pillars PL are disposed in the dispersion manner in the staircase region SR. Thereby, when the stacked body LM is formed from the stacked body in which the sacrificial layer and the insulating layer are stacked, the stacked body is supported in the staircase region SR.

As shown in FIG. 4D and FIG. 4E, the pad PDm is disposed on the insulating layer 50 with, for example, a rectangular upper surface at a joined surface of the insulating layer 50 that covers the stacked body LM, with the insulating layer 40. The shape of the pad PDm when viewed from the upper surface may be a shape other than a rectangular shape, such as a circular shape or an elliptical shape.

The insulating layer 50 is the insulating layers 52, 53, 54, . . . , and the like stacked on the upper surface of the stacked body LM as described above. The insulating layer 50 has, for example, a structure in which silicon oxide layers are stacked. Meanwhile, other insulating layers such as silicon nitride layers and silicon oxynitride layers may be interposed in the stacked structure of the insulating layer 50, and the other insulating layers may be disposed on the joined surface of the insulating layer 50.

The pad PDm has a tapered shape in which the cross-sectional area in a direction along the XY plane is reduced from the joined surface of the insulating layer 50 toward the depth direction of the insulating layer 50.

A via VAm of which a cross section in a direction along the XY plane is, for example, a circular shape is connected to a lower end portion of the pad PDm located at a predetermined depth in the insulating layer 50. The via VAm as the first via has a tapered shape in which the cross-sectional area and the diameter in the direction along the XY plane are reduced from the upper end portion connected to the pad PDm toward the depth direction of the insulating layer 50.

Further, any number of vias, wirings, and the like are further connected below the via VAm, and the above-described pillar PL, word line WL, select gate lines SGD and SGS, and source line SL are electrically connected to different pads PDm, respectively.

The pad PDm and the via VAm have a conductive layer 21m containing a predetermined metal as a core material. The conductive layer 21m is, for example, a Cu layer, and in this case, Cu contained in the pad PDm and the via VAm is an example of the first metal.

The pad PDm and the via VAm also have a conductive layer 22m containing a predetermined metal as a liner. That is, the conductive layer 22m is disposed between the insulating layer 50 and the side surface of the conductive layer 21m of the pad PDm, the lower surface of the conductive layer 21m of the pad PDm excluding the portion connected to the via VAm, and the side surface of the conductive layer 21m of the via VAm. The conductive layer 22m is, for example, a Ti layer, and in this case, Ti contained in the conductive layer 22m is an example of the second metal.

At this time, the metal contained in the conductive layer 22m is a metal that diffuses easily into the conductive layer 21m and has lower oxidation energy than the metal contained in the conductive layer 21m. In addition, the conductive layer 22m, which is the Ti layer or the like, functions as a barrier metal layer that reduces the diffusion of the conductive layer 21m, which is the Cu layer or the like, into the insulating layer 50.

The pad PDc is disposed on the insulating layer 40 with, for example, a rectangular lower surface at a joined surface of the insulating layer 40 that covers the peripheral circuit CBA, with the insulating layer 50 described above. The shape of the pad PDc when viewed from the upper surface may be a shape other than a rectangular shape, such as a circular shape or an elliptical shape.

Here, the insulating layer 40 has, for example, a structure in which a silicon oxide layer is stacked, as in the above-described insulating layer 50. Meanwhile, other insulating layers such as silicon nitride layers and silicon oxynitride layers may be interposed in the stacked structure of the insulating layer 40, and the other insulating layers may be disposed on the joined surface of the insulating layer 40.

The pad PDc has a tapered shape in which the cross-sectional area in a direction along the XY plane is reduced from the joined surface of the insulating layer 40 toward the depth direction of the insulating layer 40.

A via VAc of which a cross section in a direction along the XY plane is, for example, a circular shape is connected to an upper end portion of the pad PDc located at a predetermined depth in the insulating layer 40. The via VAc as the second via has a tapered shape in which the cross-sectional area and the diameter in the direction along the XY plane are reduced from the lower end portion connected to the pad PDc toward the depth direction of the insulating layer 40.

Further, any number of vias, wirings, and the like are connected above the via VAc, and the above-described peripheral circuit CBA is electrically connected to different pads PDm, respectively.

The pad PDc and the via VAc have a conductive layer 21c containing a predetermined metal as a core material. The conductive layer 21c is, for example, a Cu layer or the like, similar to the conductive layer 21m of the pad PDm described above. That is, the pad PDc and the via VAc also include, for example, Cu as the first metal similar to the pad PDm and the via VAm.

The pad PDm and the via VAm also have a conductive layer 22m containing a predetermined metal as a liner layer. That is, the conductive layer 22c is disposed between the insulating layer 40 and the side surface of the conductive layer 21c of the pad PDc, the upper surface of the conductive layer 21c of the pad PDc excluding the portion connected to the via VAc, and the side surface of the conductive layer 21c of the via VAc. The conductive layer 22c is, for example, a Ti layer or the like, similar to the conductive layer 22m of the pad PDm and the via VAm described above.

At this time, the metal contained in the conductive layer 22c is a metal that diffuses easily into the conductive layer 21c and has lower oxidation energy than the metal contained in the conductive layer 21c. In addition, the conductive layer 22c, which is the Ti layer or the like, also functions as a barrier metal layer that reduces the diffusion of the conductive layer 21c, which is the Cu layer or the like, into the insulating layer 40.

In addition, at least a part of the metal such as Ti contained in the conductive layers 22m and 22c is diffused into the conductive layers 21m and 21c. More specifically, in the conductive layers 21m and 21c, the metal derived from the conductive layers 22m and 22c is unevenly distributed mainly at a crystal grain boundary 21g of the metal such as Cu contained in the conductive layers 21m and 21c.

Here, when the element analysis or the like is performed on the conductive layers 21m and 21c, the metal derived from the conductive layers 22m and 22c and oxygen are detected at the crystal grain boundary 21g of the metal contained in the conductive layers 21m and 21c. Therefore, it is considered that the metal derived from the conductive layers 22m and 22c coexists with oxygen at the crystal grain boundary 21g of the metal contained in the conductive layers 21m and 21c.

In FIG. 4D described above, an interface between the conductive layers 21m and 22m of the pad PDm and the conductive layers 21c and 22c of the pad PDc is shown. However, the pad PDm and the pad PDc are joined to each other by, for example, Cu—Cu joining, and the interface between the pads may not be observed.

Even in this case, it is possible to determine that the joined surface is present between the pads PDm and PDc from any of the following points.

That is, when the pads PDm and PDc are joined to each other, the insulating layers 50 and 40 are also joined to each other, but the interface between the insulating layers 50 and 40 is often observable.

In addition, the pad PDm and the pad PDc often have different directions of a tapered shape. This is because, as will be described later, the pad PDm is processed from the frontmost surface side of the insulating layer 50, that is, the joined surface side with the insulating layer 40, and the pad PDc is processed from the frontmost surface side of the insulating layer 40, that is, the joined surface side of the insulating layer 50. Thereby, the pad PDm has a tapered shape in which the cross-sectional area is reduced toward the via VAm side below the paper surface, and the pad PDc has a tapered shape in which the cross-sectional area is reduced toward the via VAc side above the paper surface.

### Manufacturing Method of Semiconductor Memory Device

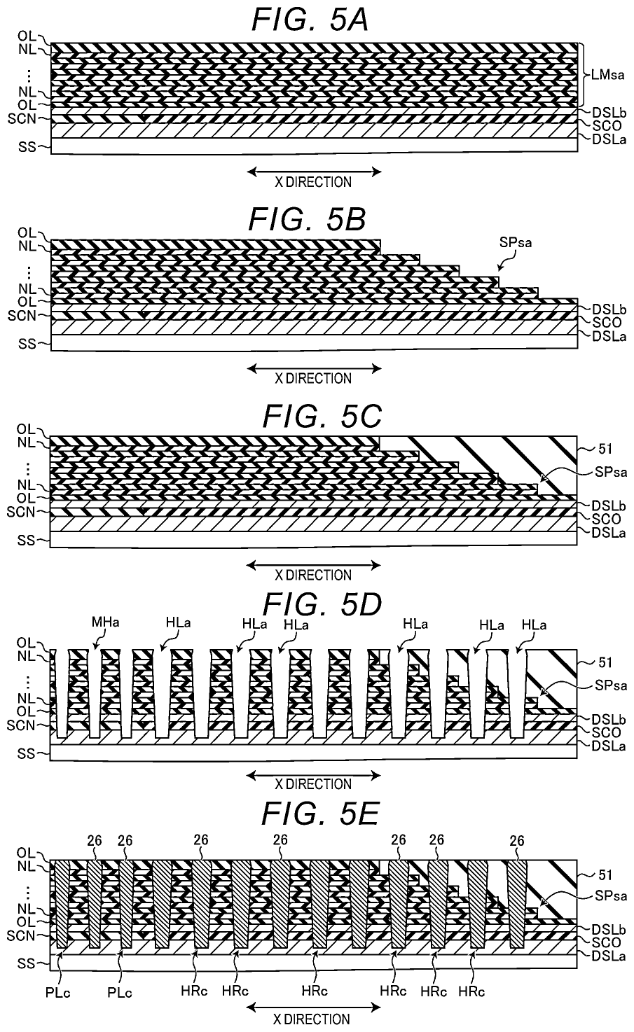

Next, a manufacturing method of the semiconductor memory device 1 according to the embodiment will be described with reference to FIGS. 5A to 10B. FIGS. 5A to 10B are views sequentially showing a part of a procedure of a method for manufacturing the semiconductor memory device 1 according to the embodiment.

First, FIGS. 5A to 5D show a stacked body LMsa which is a lower layer portion of the stacked body LM before the word line WL is formed, and a state in which various configurations are formed in the stacked body LMsa. FIGS. 5A to 5D are cross-sectional views along the X direction of a region that is to be the memory region MR and the staircase region SR later.

As shown in FIG. 5A, the lower source line DSLa, an intermediate sacrificial layer SCN or an intermediate insulating layer SCO, and the upper source line DSLb are formed in this order above a supporting substrate SS.

As the supporting substrate SS, a semiconductor substrate such as a silicon substrate, an insulating substrate such as a ceramic substrate, or a conductive substrate may be used. The insulating layer 60 (refer to FIG. 3) described above may be formed on the upper surface side of the supporting substrate SS.

The intermediate sacrificial layer SCN is formed in a region on the supporting substrate SS that is to be the memory region MR later, and the intermediate insulating layer SCO is formed in a region on the supporting substrate SS that is to be the staircase region SR later. The intermediate sacrificial layer SCN is, for example, a silicon nitride layer or the like, and is a layer that is to be replaced later with a polysilicon layer or the like to become the intermediate source line BSL. The intermediate insulating layer SCO is, for example, a silicon oxide layer or the like.

In addition, a stacked body LMsa in which a plurality of insulating layers NL and a plurality of insulating layers OL are alternately stacked by one layer is formed on the upper source line DSLb. The insulating layer NL is, for example, a silicon nitride layer or the like, and functions as a sacrificial layer that is to be replaced later with a conductive material to become the word line WL or the select gate line SGS.

As shown in FIG. 5B, the insulating layer NL and the insulating layer OL are processed in a step shape in a part region of the stacked body LMsa to form a step portion SPsa. The step portion SPsa is formed by repeating slimming of a mask pattern such as a photoresist layer and etching of the insulating layer NL and the insulating layer OL of the stacked body LMsa a plurality of times.

That is, a mask pattern is formed on the upper surface of the stacked body LMsa, and, for example, the insulating layer NL and the insulating layer OL of the exposed portion are etched and removed one by one. In addition, the end portion of the mask pattern is retreated by processing with oxygen plasma or the like to newly expose the upper surface of the stacked body LMsa, and the insulating layer NL and the insulating layer OL are further etched and removed one by one. The step portion SPsa is formed by repeating such processing a plurality of times.

As shown in FIG. 5C, an insulating layer 51 that covers the step portion SPsa and reaches the height of the upper surface of the stacked body LMsa is formed. The insulating layer 51 is also formed in the region outside the step portion SPsa.

As shown in FIG. 5D, a plurality of memory holes MHa and a plurality of holes HLa extending in the stacking direction of the stacked body LMsa are, for example, collectively formed.

The plurality of memory holes MHa penetrate the stacked body LMsa, the upper source line DSLb, and the intermediate sacrificial layer SCN and reach the lower source line DSLa. The memory holes MHa are formed in a region that is to be the memory region MR later and are portions that are to be a lower structure of the pillar PL.

The plurality of holes HLa penetrate the insulating layer 51, the stacked body LMsa, the upper source line DSLb, and the intermediate insulating layer SCO, and reach the lower source line DSLa. The holes HLa are formed in a region that is to be a staircase region SR later and are portions that are to be a lower structure of the columnar portion. As described above, the lower structure of the columnar portion supports these configurations in the staircase region SR when the stacked body LMsa is formed into from the stacked body LMa.

As shown in FIG. 5E, inside of the memory holes MHa and the holes HLa are filled with the sacrificial layer 26 such as an amorphous silicon layer.

Thereby, the pillar PLc in which the plurality of the memory holes MHa is filled with the sacrificial layer 26 is formed in the region that is to be the memory region MR later. In addition, a columnar portion HRc in which the plurality of the holes HLa is filled with the sacrificial layer 26 is formed in a region that is to be the staircase region SR later.

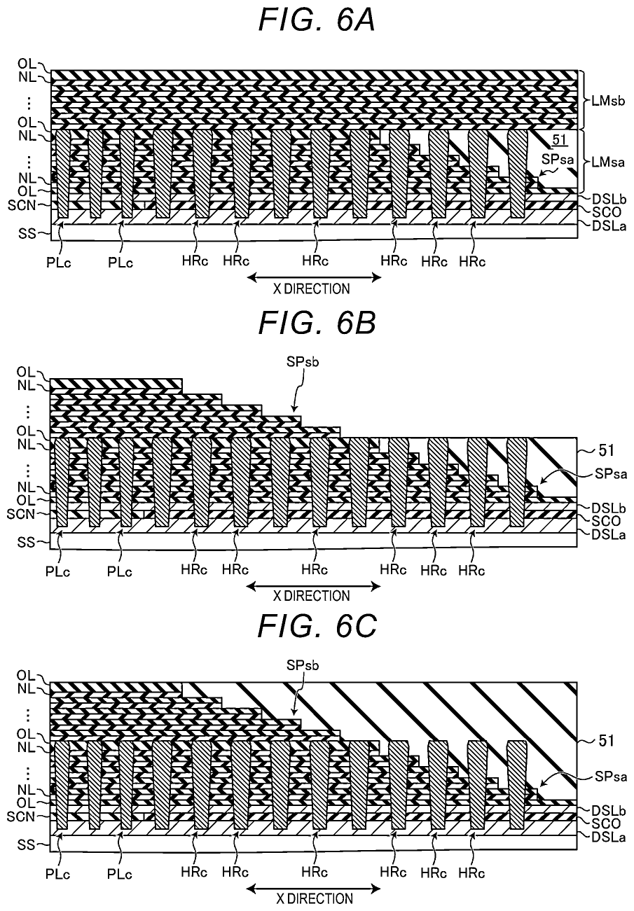

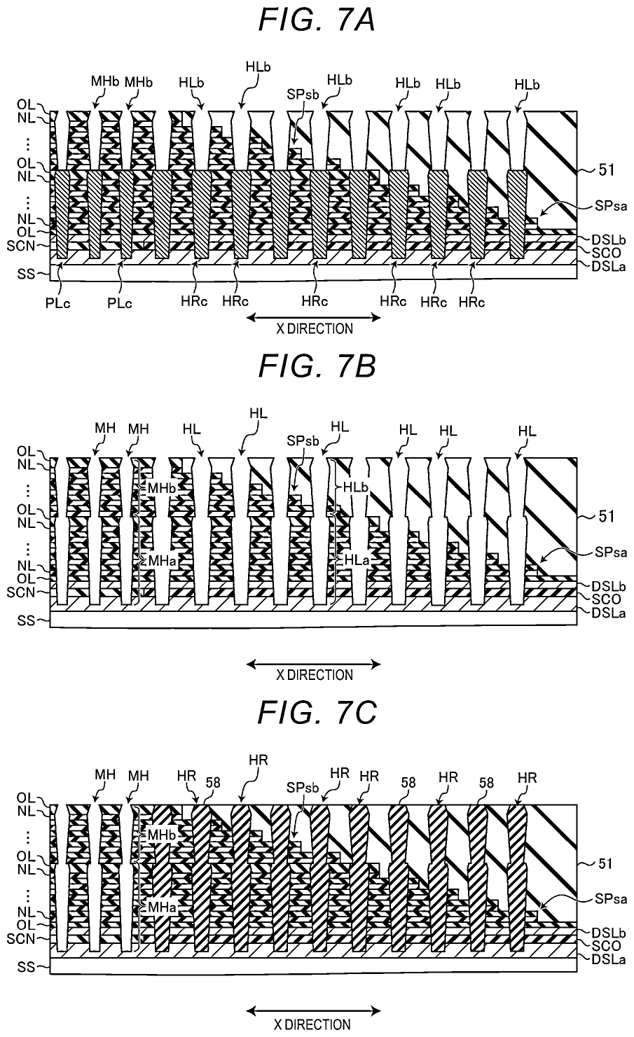

Next, FIGS. 6A and 7C show a stacked body LMsb which is an upper layer portion of the stacked body LM before the word line WL is formed, and a state in which various configurations are formed in the stacked body LMsb. FIGS. 6A and 7C are cross-sectional views along the X direction of a region that is to be the memory region MR and the staircase region SR later, as in FIGS. 5A to 5E described above.

As shown in FIG. 6A, the stacked body LMsb that covers over the stacked body LMsa and over the insulating layer 51 of the step portion SPsa and in which the plurality of insulating layers NL and the plurality of insulating layers OL are alternately stacked one by one is formed. The sacrificial layer NL of the stacked body LMsb is to be replaced later with a conductive layer to become the word line WL or the select gate line SGD.

As shown in FIG. 6B, in a part region of the stacked body LMsb, the insulating layer NL and the insulating layer OL are processed in a step shape to form a step portion SPsb. The step portion SPsb is formed by repeating slimming of a mask pattern such as a photoresist layer and etching of the insulating layer NL and the insulating layer OL of the stacked body LMsb a plurality of times, as in the processing shown in FIG. 5B described above.

At this time, the uppermost stage of the step portion SPsa and the lowermost stage of the step portion SPsb are brought close to each other to form the step portion SPsb. Thereby, the step portions SPsa and SPsb are disposed to be continuously connected from the lower layer side to the upper layer side of the stacked bodies LMsa and LMsb. In addition, the upper end portion of the columnar portion HRc formed in the step portion SPsa is exposed on the upper surface of the insulating layer 51 by removing the stacked body LMsb on the insulating layer 51 that covers the step portion SPsb.

As shown in FIG. 6C, the insulating layer 51 that covers the step portion SPsb and covers the insulating layer 51 formed on the step portion SPsa is formed. Thereby, the insulating layer 51 reaches the height of the upper surface of the stacked body LMsb.

As shown in FIG. 7A, for example, a plurality of memory holes MHb and a plurality of holes HLb extending in the stacking direction of the height position of stacked body LMsa are, for example, collectively formed.

The plurality of memory holes MHb penetrate the stacked body LMsb and reach the upper end portions of the pillars PLC formed in the stacked body LMsa, respectively. The memory holes MHb are disposed in a region that is to be the memory region MR later and are portions that are to be an upper structure of the pillar PL.

The plurality of holes HLb penetrate the insulating layer 51 and the stacked body LMsb and reach the upper end portions of the columnar portions HRc formed in the stacked body LMsa, respectively. The hole HLb is disposed at a position overlapping the step portions SPsa and SPsb in the stacking direction, and is a portion that is an upper structure of the columnar portion. As described above, the upper structure of the columnar portion supports these configurations in the staircase region SR when the stacked body LMsb is formed from the stacked body LMb.

As shown in FIG. 7B, the sacrificial layer 26 is removed from the pillars PLC and the columnar portions HRc respectively connected to the lower end portions of the memory holes MHb and the holes HLb via the memory holes MHb and the holes HLb.

As a result, memory holes MHa are opened at the bottom of each of the plurality of memory holes MHb, and the plurality of memory holes MH, which penetrate the insulating layer 51, the stacked bodies LMsb and LMsa, the upper source line DSLb, and the intermediate sacrificial layer SCN and reach the lower source line DSLa, are formed.

In addition, the holes HLa are opened at the bottom of each of the plurality of holes HLb, and the plurality of holes HL, which penetrate the insulating layer 51, the stacked bodies LMsb and LMsa, the upper source line DSLb, and the intermediate insulating layer SCO and reach the lower source line DSLa, are formed.

As shown in FIG. 7C, inside of each of the plurality of holes HL are filled with the insulating layer 58 such as the silicon oxide layer, the plurality of columnar portions HR, which penetrate the insulating layer 51, the stacked bodies LMsb and LMsa, the upper source line DSLb, and the intermediate insulating layer SCO and reach the lower source line DSLa, are formed.

When the plurality of holes HL are filled with the insulating layer 58, the plurality of memory holes MH formed in the region that is to be the memory region MR later are protected with a photoresist layer or the like.

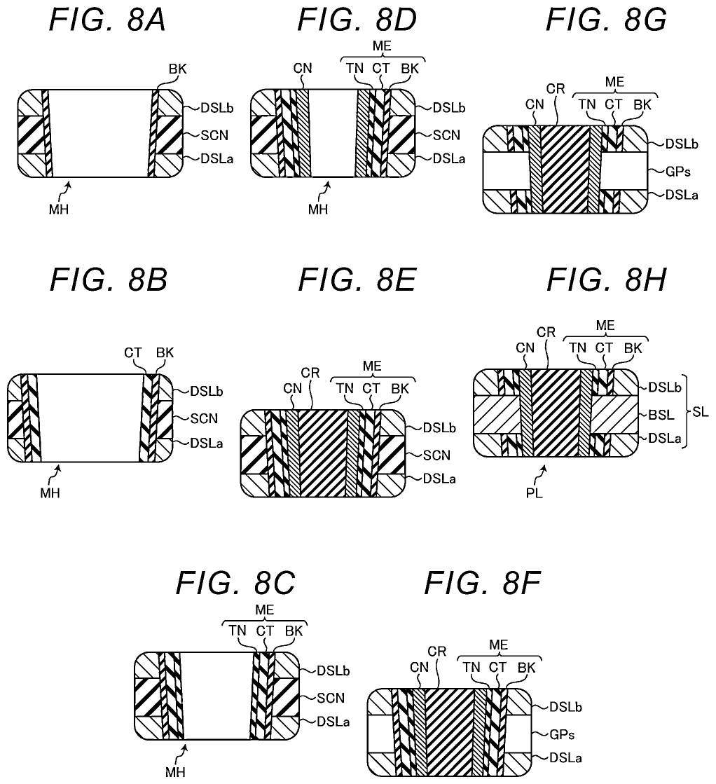

Next, FIGS. 8A to 8H show states in which a multilayer structure or the like is formed in the memory hole MH to form the pillar PL. FIGS. 8A to 8H are enlarged cross-sectional views of the memory hole MH at the height position of the intermediate sacrificial layer SCN.

As shown in FIG. 8A, the block insulating layer BK such as a silicon oxide layer is formed on the side walls of the memory hole MH and the hole HL.

As shown in FIG. 8B, the charge storage layer CT is formed on the side wall of the memory hole MH via the block insulating layer BK.

As shown in FIG. 8C, the tunnel insulating layer TN is formed on the side wall of the memory hole MH via the block insulating layer BK and the charge storage layer CT.

As described above, the memory layer ME including the block insulating layer BK, the charge storage layer CT, and the tunnel insulating layer TN in this order from the outer peripheral side of the memory hole MH is formed.

As shown in FIG. 8D, the channel layer CN is formed on the side wall of the memory hole MH via the memory layer ME.

As shown in FIG. 8E, the core layer CR fills the voids remaining in the memory hole MH.

Thereafter, the core layer CR of the upper end portion of the memory hole MH is removed to fill the semiconductor layer, and the cap layer CP (refer to FIG. 4A) is formed.

In addition, a slit (not shown) that extends in the direction along the X direction in the stacked bodies LMsa and LMsb, penetrates the stacked bodies LMsa and LMsb, and upper source line DSLn, and reaches the intermediate sacrificial layer SCN or the intermediate insulating layer SCO is formed. The slit has a configuration in which the insulating layer 55 is to be filled later to form the plate-shaped portion PT.

As shown in FIG. 8F, a chemical solution such as hot phosphoric acid is injected through the slit to remove the intermediate sacrificial layer SCN and form a gap layer GPs between the lower source line DSLa and the upper source line DSLb. Thereby, a part of the block insulating layer BK formed on the side wall of the memory hole MH is exposed in the gap layer GPs.

At this time, a protective layer such as a silicon oxide layer is formed on the side wall of the slit, so that the insulating layer NL in the stacked bodies LMsa and LMsb is not removed. The intermediate sacrificial layer SCN is removed only by a chemical solution injected through the lower end portion of the slit. In addition, the intermediate insulating layer SCO formed in a region that is to be the staircase region SR later instead of the intermediate sacrificial layer SCN is not removed by the chemical solution. Therefore, the gap layer GPs is not formed in the region that is to be the staircase region SR later.

As shown in FIG. 8G, different chemical solutions are injected through the slits, and the block insulating layer BK, the charge storage layer CT, and the tunnel insulating layer TN exposed in the gap layer GP are subsequently removed. Thereby, a part of the side surface of the channel layer CN is exposed in the gap layer GPs.

As shown in FIG. 8H, a raw material gas such as polysilicon is injected through the slit to fill the gap layer GPs with a polysilicon layer. Thereby, the intermediate source line BSL is formed between the lower source line DSLa and the upper source line DSLb.

As described above, the pillar PL connected to the source line SL on a part of the side surface of the channel layer CN is formed.

Thereafter, the protective layer on the side wall of the slit is removed, and a chemical solution such as hot phosphoric acid is injected through the slit to remove the insulating layer NL in the stacked bodies LMsa and LMsb. In addition, a raw material gas such as tungsten is injected through the slit to fill the void from which the insulating layer NL is removed in the stacked bodies LMsa and LMsb with a tungsten layer or the like.

As described above, the stacked body LM in which the plurality of word lines WL and the plurality of insulating layers OL are alternately stacked, and the select gate lines SGD and SGS are further provided is formed.

The stacked bodies LMsa and LMsb from which the insulating layers NL are removed and which have voids in a multilayered manner have a fragile structure. In the region that is to be the memory region MR later, the plurality of pillars PL support the fragile stacked bodies LMsa and LMsb. On the other hand, in the step portions SPsb and SPsa, the plurality of columnar portions HR support the stacked bodies LMsa and LMsb.

As a result, the remaining insulating layer OL in the stacked bodies LMsa and LMsb is prevented from being bent, and the stacked bodies LMsa and LMsb themselves having the voids are prevented from being distorted or collapsed.

As described above, the processing of forming the intermediate source line BSL from the intermediate sacrificial layer SCN and the processing of forming the word line WL from the insulating layer NL are also referred to as replacement processing.

Thereafter, the insulating layer 54 is filled in the slit to form the plate-shaped portion PT. In addition, a groove that penetrates one layer or a plurality of layers including the uppermost layer of the stacked body LMb is formed, and the insulating layer 56 is filled in the groove to form the separation layer SHE that partitions one or more upper layers of the stacked body LMb into a pattern of the select gate line SGD.

In addition, a plurality of contacts CC that penetrate the insulating layer 51 and respectively reach the word lines WL and the select gate lines SGD and SGS that configure each stage of the step portion SP are formed.

Subsequently, the insulating layer 52 is formed on the upper surface of the insulating layer 51 that covers the upper surface of the stacked body LM and the staircase region SR, and the plug CH connected to the pillar PL through the insulating layer 52 is formed. Further, the insulating layer 53 is formed on the insulating layer 52, and the bit line BL and the like connected to the plug CH are formed. Thereafter, the insulating layers 54, . . . , and the like are subsequently formed, and the plugs, the wirings, and the like are formed for any number of staked layers.

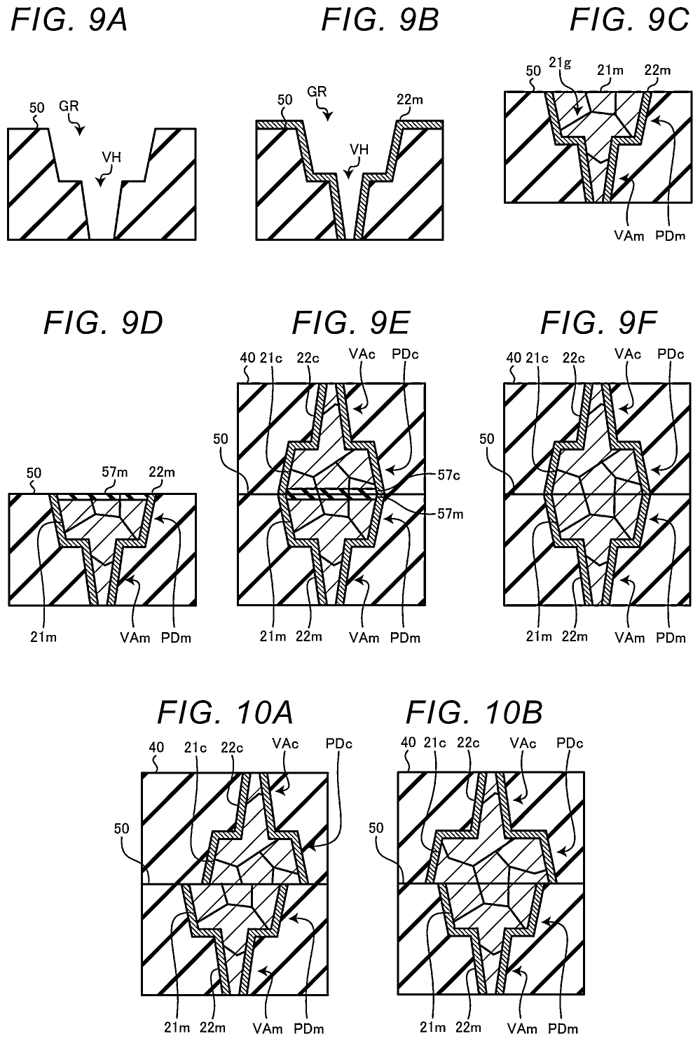

Next, FIGS. 9A to 9F show states in which the via VAm and the pad PDm are formed in the insulating layer 50 and the pad PDc on the insulating layer 40 side that covers the peripheral circuit CBA is joined. FIGS. 9A to 9F are cross-sectional views of a joining portion of the insulating layer 50 joined to the insulating layer 40.

As shown in FIG. 9A, a via hole VH and a trench GR connected to the upper end portion of the via hole VH are formed by performing etching processing or the like from the frontmost surface side of the insulating layer 50. The via hole VH reaches other wirings (not shown) formed in the insulating layer 50.

The via hole VH and the trench GR are obtained, for example, by forming the via hole VH reaching a predetermined depth from the frontmost surface of the insulating layer 50 and then expanding the upper end portion of the via hole VH into the shape of the trench GR. Alternatively, for example, after forming the trench GR reaching the predetermined depth from the frontmost surface of the insulating layer 50, the via hole VH extending to a deeper position of the insulating layer 50 from the bottom surface of the trench GR may be formed.

In any of the processing methods, by performing etching processing or the like from the frontmost surface side of the insulating layer 50, both the trench GR and the via hole VH have a tapered shape in which the cross-sectional area along the XY plane is reduced from the upper end portion side toward the lower end portion side.

As shown in FIG. 9B, the conductive layer 22m, such as the Ti layer, that covers the side surface and the bottom surface of the trench GR and the side surface of the via hole VH is formed. At this time, the conductive layer 22m is also formed on the upper surface of the insulating layer 50.

As shown in FIG. 9C, the Cu material or the like is filled in the voids remaining in the trench GR and the via hole VH to form the conductive layer 21m. At this time, the Cu material is filled in the trench GR and the via hole VH by plating or the like, and the conductive layer 21m having the crystal grain boundary 21g of a metal such as Cu is formed. At this time, the conductive layer 21m is also formed on the upper surface of the insulating layer 50 via the conductive layer 22m. However, thereafter, the conductive layers 21m and 22m on the upper surface of the insulating layer 50 are subsequently removed by a chemical mechanical polishing (CMP) or the like.

Thereby, the pad PDm in which the upper surface is exposed on the frontmost surface of the insulating layer 50 and the via VAm connected to the lower end portion of the pad PDm at the upper end portion are formed. A method of collectively forming the pad PDm and the via VAm in this manner is also referred to as a dual damascene method.

The metal such as Cu in the pad PDm may be chemically oxidized by performing CMP processing or the like on the surface of the conductive layer 21m filled in the trench GR and the via hole VH. In addition, after the above-described configuration is formed, the metal such as Cu in the pad PDm exposed on the surface of the insulating layer 50 may be naturally oxidized by being placed in the atmosphere for a predetermined time.

The oxide layer 57m on the upper surface of the pad PDm shown in FIG. 9D is an oxide layer formed by chemical oxidation, natural oxidation, or the like.

On the other hand, the peripheral circuit CBA is formed on the semiconductor substrate SB, which is a separate body from the supporting substrate SS on which the stacked body LM is formed, and is covered with the insulating layer 40. In the insulating layer 40, a contact, a via, a wiring, and the like for drawing out the peripheral circuit CBA to the surface of the insulating layer 40 are formed, and the contact, the via, the wiring, and the like are connected to the pad PDc and the via VAc on which the frontmost surface of the insulating layer 40 is formed on a side.

At this time, the pad PDc and the via VAc in the insulating layer 40 are also formed in the same manner as in FIGS. 9A to 9C. The pads PDc and the via VAc have a tapered shape in which the cross-sectional area along the XY plane is reduced from the frontmost surface side of the insulating layer 40 toward a direction in which the depth increases, by being formed by etching processing or the like from the frontmost surface side of the insulating layer 40.

As shown in FIG. 9E, the insulating layer 50 on the supporting substrate SS side is joined to the insulating layer 40 on the semiconductor substrate SB side. The insulating layers 50 and 40 may be joined to each other by, for example, being activated in advance by plasma processing or the like. At this time, the position alignment of the supporting substrate SS and the semiconductor substrate SB is performed such that the pad PDm formed in the insulating layer 50 and the pad PDc formed in the insulating layer 40 overlap each other in the vertical direction.

An oxide layer 57c is also formed on the surface of the pad PDc at the time of joining the insulating layers 50 and 40 to each other.

As shown in FIG. 9F, after the insulating layers 50 and 40 are joined to each other, an annealing process is performed to join the pads PDm and PDc to each other. By the annealing process, a part of the metal such as Ti in the conductive layers 22m and 22c is diffused into the conductive layers 21m and 21c.

In addition, the oxide layers 57m and 57c on the upper surfaces of the pads PDm and PDc are erased by the annealing process. It is presumed that this is because the metal diffused into the conductive layers 21m and 21c and derived from the conductive layers 22m and 22c reduces the oxide layers 57m and 57c on the upper surfaces of the pads PDm and PDc. According to the result of the above-described element analysis, it is shown that the metal derived from the conductive layers 22m and 22c is unevenly distributed in the crystal grain boundary 21g of the metal in the conductive layers 21m and 21c together with oxygen.

A part of the metal in the conductive layers 22m and 22c is diffused into the conductive layers 21m and 21c while reducing the oxide layers 57m and 57c. As a result, the layer thickness of the conductive layers 22m and 22c may be slightly reduced in a part or entirely.

After the oxide layers 57m and 57c on the surfaces are erased, the pad PDm and the pad PDc are joined to each other by, for example, Cu—Cu joining by continuing the annealing process.

As described above, the supporting substrate SS and the semiconductor substrate SB are bonded to each other.

Thereafter, the supporting substrate SS is ground and removed to expose the source line SL, and the electrode film EL is connected via the insulating layer 60 in which the plug PG is formed. Further, by individually dividing the semiconductor substrate SB by dicing, the semiconductor memory device 1 in which the above-described chips 2 and 3 (refer to FIG. 3) are joined to each other is obtained.

As described above, the semiconductor memory device 1 of the embodiment is manufactured.

The interface between the pads PDm and PDc may be erased by joining the pads PDm and PDc to each other as described above. Even in this case, the joining interface between the insulating layers 50 and 40 may be observed, and the joined surface between the pads PDm and PDc may be distinguished by observing the direction of the tapered shape of the pads PDm and PDc.

Hereinafter, a method for identifying the joined surfaces of the pads PDm and PDc other than the above will be described with reference to FIGS. 10A and 10B. FIGS. 10A and 10B are cross-sectional views of a joining portion between the insulating layer 50 and the insulating layer 40, as in FIGS. 9A to 9F described above.

As shown in FIG. 10A, the positional misalignment may occur when the pads PDm and PDc overlap each other in the vertical direction.

As described above, when the pads PDm and PDc are joined to each other, the position alignment of the supporting substrate SS and the semiconductor substrate SB is performed so that the pads PDm and PDc overlap each other in the vertical direction. However, due to the position alignment error or the like at this time, the pad PDm and the pad PDc may be slightly misaligned and joined.

In this way, for example, it may be distinguished that the joined surface is present between the pads PDm and PDc by observing the pads PDm and PDc in which the positional misalignment occurs.

As shown in FIG. 10B, the size of the pad PDm and the size of the pad PDc may be different. A reason why the sizes of the pads PDm and PDc are different from each other may be the designed sizes of the pads PDm and PDc which are different from each other. Alternatively, the pads PDm and PDc may have different sizes due to processing errors and the like at the time of formation, because the pads PDm and PDc are formed separately.

As described above, it is possible to distinguish that the joined surface is present between the pads PDm and PDc by observing the state in which the sizes of the pads PDm and PDc are different.

### Overview

In semiconductor devices, some may be constituted by having different elements formed on the different substrates and bonding the substrates to each other. In order to electrically connect these elements, pads electrically connected to each element are formed on the joined surface. When the substrate is bonded, the pads may be joined to each other to electrically connect different elements to each other.

However, after the pads are respectively formed, an oxide layer may be formed on the surfaces of the pads before the pads are joined to each other. When these pads are joined to each other, the oxide layer on the surfaces of these pads may be a factor that inhibits electrical conduction between the pads.

On the other hand, in addition to the pads for electrically connecting different elements to each other, the semiconductor device includes a plurality of contacts, vias, wirings, and the like, and a barrier metal layer may also be used to reduce the diffusion of a metal material constituting the plurality of contacts, vias, wirings, and the like into an insulating layer. When the metal material is Cu, a Ta layer is generally used as the barrier metal layer.

The present inventors focused on the barrier metal layer and considered using a metal with high diffusivity in Cu and high reducibility as a constituent material for the barrier metal layer. As a result, it was found that the oxide layer on the pad surface was erased during the annealing process at the time of joining the pads.

According to the semiconductor memory device 1 of the embodiment, each of the pads PDm and PDc has the conductive layers 22m and 22c disposed between the insulating layers 50 and 40, and the conductive layers 22m and 22c contain a metal having oxidation energy lower than that of the metal of the conductive layers 21m and 21c of the pads PDm and PDc. As a result, it is possible to prevent the conductive connection between the pads PDm and PDc from being inhibited by the oxide layers on the pad surfaces PDm and PDc.

According to the semiconductor memory device 1 of the embodiment, the metal contained in the conductive layers 22m and 22c is titanium, and the conductive layers 22m and 22c are barrier metal layers. By using Ti as the metal of the conductive layers 22m and 22c, the conductive layers 22m and 22c may function as a barrier metal layer.

According to the semiconductor memory device 1 of the embodiment, the pillar PL having the channel layer CN that penetrates the stacked body LM is provided in the stacking direction of the stacked body LM disposed in the insulating layer 50, and the pillar PL is electrically connected to the pad PDm. A peripheral circuit CBA including a plurality of transistors TR disposed in the insulating layer 40 is provided, and the peripheral circuit CBA is electrically connected to the pad PDc.

In this way, by forming and bonding different elements on different substrates such as the supporting substrate SS and the semiconductor substrate SB, a semiconductor device having an advanced and complicated function may be configured in a space-saving manner.

In the above-described embodiment, the pillar PL is connected to the source line SL on the side surface of the channel layer CN, but the present disclosure is not limited thereto. For example, the pillar may be connected to the source line at the lower end portion of the channel layer by removing the memory layer of the bottom surface of the pillar. In this case, the source line may be formed after the supporting substrate SS and the semiconductor substrate SB are bonded.

More specifically, after the supporting substrate SS and the semiconductor substrate SB are bonded to each other, when the supporting substrate SS is ground and removed, the grinding may be continued until the lower end portion of the pillar PL is exposed, and the source line may be formed to cover the exposed lower end portion of the pillar PL. At this time, a source line of a metal layer may be formed instead of the polysilicon layer or the like.

In addition, in the above-described embodiment, the stacked body LM has a 2 Tier structure including two stacked bodies LMa and LMb. However, the number of Tiers of the stacked body may be 1 Tier or may be 3 Tiers or more.

In addition, in the above-described embodiment, the staircase region SR is disposed at an end portion of the stacked body LM in the X direction. However, by digging down the center portion of the stacked body in a step shape, a staircase region may be disposed in the center portion of the stacked body when viewed in the stacking direction.

### MODIFICATION EXAMPLE 1

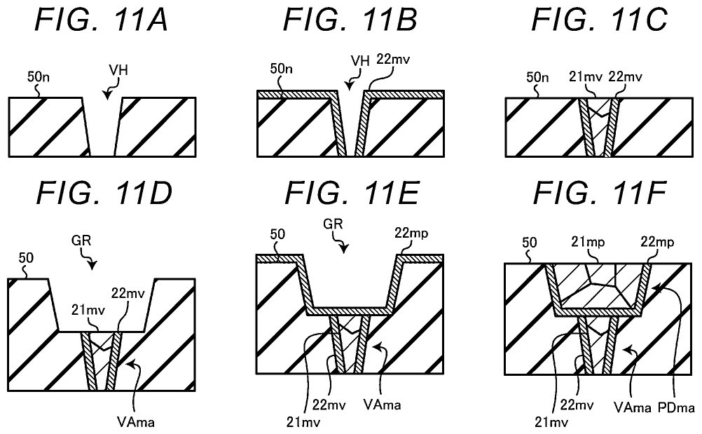

Next, a semiconductor memory device of Modification Example 1 according to the embodiment will be described with reference to FIGS. 11A to 11F. In the semiconductor memory device of Modification Example 1, the formation procedure of the pad PDma and the via VAma is different from the above-described embodiment.

In the following drawings, the same reference numerals may be given to the same configuration as in the above-described embodiment, and the description thereof may be omitted.

FIGS. 11A to 11F are views showing a part of the procedure of the method for manufacturing the semiconductor memory device according to Modification Example 1 of the embodiment. More specifically, FIGS. 11A to 11F are cross-sectional views of a joining portion of the insulating layer 50 joined to the insulating layer 40 in the semiconductor memory device during the manufacturing of Modification Example 1.

An insulating layer 50n shown in FIG. 11A covers the stacked body LM, the pillar PL, and the like, and the insulating layers 52, 53, 54, . . . , and the like described above are subsequently stacked. In the insulating layer 50n, up to the wiring (not shown) immediately below the via VAma connected to the pad PDma that is to be formed later is formed, and the insulating layer 50n has a thickness equal to the height of the via VAma that is to be formed later on the wiring.

As shown in FIG. 11A, the via hole VH is formed by performing etching processing or the like from the frontmost surface side of the insulating layer 50n.

As shown in FIG. 11B, a conductive layer 22mv that covers the side surface of the via hole VH is formed. The conductive layer 22mv as the fifth metal layer is, for example, a Ti layer containing Ti, in the same manner as the conductive layer 22m of the above-described embodiment. The conductive layer 22mv is also formed on the upper surface of the insulating layer 50n.

As shown in FIG. 11C, a conductive layer 21mv as the fourth metal layer is formed by filling the voids remaining in the via hole VH with a Cu material or the like. The conductive layer 21mv is also formed on the upper surface of the insulating layer 50n via the conductive layer 22mv. The conductive layers 21mv and 22mv are subsequently removed by CMP or the like. Thereby, the via VAma as the first via is formed.

As shown in FIG. 11D, the insulating layer 50 is obtained by stacking an insulating layer such as a silicon oxide layer having a thickness equal to the height of the pad PDma that is to be formed later to cover the via VAma. In addition, the trench GR is formed in the insulating layer 50 in the stacked portion by performing etching processing or the like from the frontmost surface side of the insulating layer 50.

As shown in FIG. 11E, a conductive layer 22mp that covers the side surfaces and the bottom surface of the trench GR is formed. At this time, the conductive layer 22mp that also covers the upper end portion of the via VAma is formed, and the conductive layer 22mp is also formed on the upper surface of the insulating layer 50. The conductive layer 22mp as the second metal layer is, for example, a Ti layer containing Ti, in the same manner as the conductive layer 22m of the above-described embodiment.

As shown in FIG. 11F, a conductive layer 21mp as the first metal layer is formed by filling the voids remaining in the via trench GR with a Cu material or the like. The conductive layer 21mp is also formed on the upper surface of the insulating layer 50 via the conductive layer 22mp. The conductive layers 21mp and 22mp are subsequently removed by CMP or the like. Thereby, the pad PDma, as the first pad, to which the via VAma is connected to the lower end portion is formed.

A method of forming the pad PDma and the via VAma in separate steps as described above is also referred to as a single damascene method or the like. According to such a formation method, the conductive layer 22mp of the pad PDma is interposed between the pad PDma and the via VAma.

Thereafter, the pad PDm is joined to the pad formed in the insulating layer 40, as in the above-described embodiment. The pad on the insulating layer 40 side may be formed by the dual damascene method as in the above-described embodiment, or may be formed by the single damascene method as in the pad PDma of Modification Example 1.

According to the semiconductor memory device of Modification Example 1, the same effects as those of the semiconductor memory device 1 of the above-described embodiment are obtained.

### MODIFICATION EXAMPLE 2

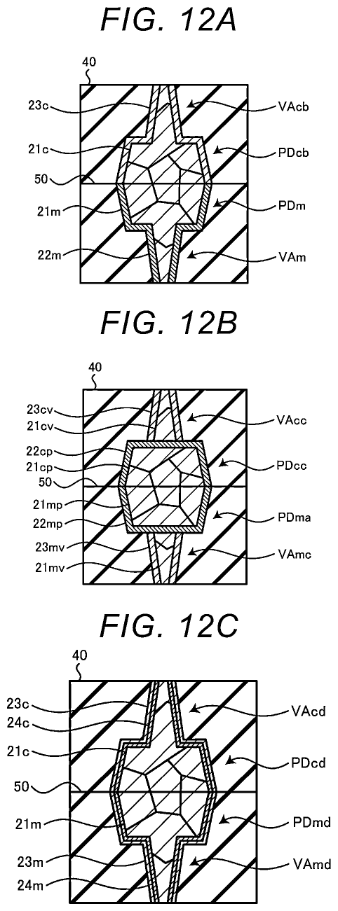

Next, a semiconductor memory device of Modification Example 2 of the embodiment will be described with reference to FIGS. 12A to 12C. In the semiconductor memory device of Modification Example 2, pads PDcb, PDmd, and PDcd and vias VAcb, VAmc, VAcc, VAmd, and VAcd, and the like have layers different from the pads PDm and PDc and the vias VAm and VAc of the above-described embodiment, respectively.

In the following drawings, the same reference numerals may be given to the same configuration as in the above-described embodiment, and the description thereof may be omitted.

FIGS. 12A to 12C are cross-sectional views of a joining portion of insulating layers 40 and 50 of the semiconductor memory device according to Modification Example 2 of the embodiment.

In the example shown in FIG. 12A, the pad PDm and the via VAm provided in the insulating layer 50 have the same configuration as the above-described embodiment. That is, the pads PDm and the vias VAm are formed by a dual damascene method and have a conductive layer 22m containing a metal such as Ti.

On the other hand, the pad PDcb and the via VAcb provided in the insulating layer 40 have a conductive layer 23c different from the conductive layer 22c of the above-described embodiment, as a barrier metal layer. More specifically, the pad PDcb and the via VAcb are formed by a dual damascene method, and have a conductive layer 23c containing a metal such as Ta as a third metal.

As described above, the conductive layer containing Ta or the like is frequently used as a barrier metal layer in combination with a Cu material. On the other hand, Ta and the like do not have high diffusibility into the Cu material, and do not have a property of reducing an oxide layer formed on the surface of the pads PDm and PDcb, for example.

However, at least one side of the pad PDm of the pads PDm and PDcb have the conductive layer 22m containing Ti or the like, thereby the oxide layer formed on the surface of the pads PDm and PDcb may be erased.

In the example shown in FIG. 12B, the pad PDma and the via VAmc provided in the insulating layer 50 and the pad PDcc and the via VAcc provided in the insulating layer 40 are formed by the single damascene method, respectively. In addition, both of the pads PDma and PDcc have conductive layers 21mp and 21cp containing a metal such as Cu and conductive layers 22mp and 22cp containing a metal such as Ti, as in the conductive layers 21m, 22m, 21c, and 22c of the above-described embodiment.

On the other hand, the vias VAmc and VAcc provided in the insulating layers 50 and 40, respectively, each have conductive layers 21mv and 21cv containing a metal such as Cu, and conductive layers 23mv and 23cv containing a metal such as Ta, instead of the conductive layers 22m and 22c of the above-described embodiment.

As described above, when the pad PDma and the via VAmc, or the pad PDcc and the via VAcc are formed by the single damascene method, the liner of the conductive layer containing the different metal materials may be formed on the pad PDmc and the pad PDcc, and the via VAmc and the via VAcc, respectively. At this time, as described above, when at least one of the pads PDma and PDcc has the conductive layers 22mp and 22cp containing a metal such as Ti, the oxide layers on the surfaces of the pads PDma and PDcc may be erased.

Therefore, as shown in the example of FIG. 12B, for example, a liner of the conductive layers 22mp and 22cc containing a metal such as Ti may be formed on the pads PDma and PDcc, and the conductive layer 23mv and 23cv not containing Ti, such as Ta, may be formed on the vias VAma and VAcc.

At this time, instead of using the conductive layers 23mv and 23cv not containing Ti as the liner layers of the vias VAm and VAc, or in addition to using the conductive layers 23mv and 23cv not containing Ti as the liner layers of the vias VAm and VAc, at least any one of the conductive layers 21mv and 21cv serving as the core material of the vias VAma and VAcc may be configured to contain another metal such as tungsten instead of Cu. As described above, the combination of the material of the liner layer and the core material in the pad PDma and the via VAmc or the pad PDcc and the via VAcc when the single damascene method is used may be changed in various ways.

The conductive layer 21cp is an example of the first metal layer, and the conductive layer 22cp is an example of the third metal layer. In addition, the conductive layer 21cv is an example of a sixth metal layer, and the conductive layer 23cv is an example of a seventh metal layer.

In the example shown in FIG. 12C, the pad PDmd and the via VAmd provided in the insulating layer 50 and the pad PDcd and the via VAcd provided in the insulating layer 40 are formed by the dual damascene method, respectively.

In addition, the pads PDmd and PDcd have, inside the conductive layers 23m and 23c containing a metal such as Ta, conductive layers 24m and 24c containing a metal different from Ti that diffuse easily into the conductive layers 21m and 21c such as the Cu material of the pad PDmd and PDcd and have lower oxidation energy than the Cu material of the conductive layers 21m and 21c. That is, the conductive layers 24m and 24c are interposed between the conductive layer 23m and the conductive layer 21m, and between the conductive layer 23c and the conductive layer 21c in each of the pads PDmd and PDcd.

As a metal that is easily diffused into the Cu material or the like of the conductive layers 21m and 21c and has lower oxidation energy than the Cu material or the like of the conductive layers 21m and 21c, in addition to Ti, Mn, Al, Mg, and the like are exemplified. Therefore, the conductive layers 24m and 24c as the second and third metal layers may contain at least any of Mn, Al, and Mg.

However, these Mn, Al, and Mg do not have a function as a barrier metal layer at least in a single state. Therefore, the pads PDmd and PDcd each have the conductive layer 23m or 23c containing Ti or the like functioning as a barrier metal layer in addition to the conductive layers 24m and 24c.

As described above, the conductive layers containing various metal materials may be used in various combinations in addition to the configurations described with reference to FIGS. 12A to 12C as the liner of the pads and vias in the insulating layer 50 and the pads and vias in the insulating layer 40.

According to the semiconductor memory device of Modification Example 2, the same effects as those of the semiconductor memory device 1 of the above-described embodiment are obtained.

In the above-described embodiment and Modification Examples 1 and 2, the semiconductor device is assumed to be a semiconductor memory device 1 obtained by bonding an element including the memory cell MC or the like, and an element such as the peripheral circuit CBA that controls the electrical operation of the memory cell MC. However, the semiconductor device to which the pad of the embodiment and Modification Examples 1 and 2 may be applied is not limited to this, and may be an image sensor in which a pixel and a circuit element are bonded, a semiconductor device in which a memory element and a logic element different from those of the semiconductor memory device 1 are bonded, and the like.

In addition, in the above-described embodiment and Modification Examples 1 and 2, for example, a Ti layer is used as a liner such as the conductive layers 22m and 22c having a function as a barrier metal layer and a function for reducing the oxide layer. However, it is known that a Ti—Mn alloy also has a barrier property. Therefore, the Ti—Mn alloy may also be used as a liner having a function as a barrier metal layer and a function for reducing an oxide layer.

As described above, in the semiconductor device of the embodiment, as a conductive layer that covers a Cu material or the like serving as a core material of a pad, a conductive layer including at least any one of single or alloyed Ti, Mn, Al, and Mg, and having a function as a barrier metal layer or not having the function, may be appropriately used.

At this time, when a layer containing a metal that does not have a function as a barrier metal layer is used as the conductive layer that covers the Cu material or the like serving as the core material of the pad, a barrier metal layer may be additionally provided on an outside of the conductive layer. The barrier metal layer provided separately may be a single metal layer such as a Ta layer as in Modification Example 2 shown in FIG. 12C described above, or may be a metal nitride layer such as a TaN layer or a TiN layer.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device, comprising:
a first chip including a first insulating layer;
a second chip bonded to the first chip and including a second insulating layer; and
a pad provided around a bonded surface between the first chip and the second chip,
wherein the pad includes a first metal layer including a first metal, a second metal layer disposed between the first metal layer and the first insulating layer, and a third metal layer disposed between the first metal layer and the second insulating layer,
at least one of the second metal layer or the third metal layer include a second metal having oxidation energy lower than oxidation energy of the first metal, and
the first metal layer further includes the second metal.

2. The semiconductor device according to claim 1,
wherein at least a portion of the second metal in the first metal layer is unevenly distributed at a crystal grain boundary of the first metal layer.

3. The semiconductor device according to claim 1,
wherein the first metal is copper, and
the second metal includes at least one of titanium, manganese, aluminum, or magnesium.

4. The semiconductor device according to claim 3,
wherein the second metal is contained in at least the second metal layer,
the second metal includes at least titanium, and
the second metal layer is a barrier metal layer.

5. The semiconductor device according to claim 3,
wherein the second metal is contained in at least the second metal layer, and
the pad includes a barrier metal layer interposed between the second metal layer and the first insulating layer.

6. The semiconductor device according to claim 1, further comprising:
a first via disposed in the first insulating layer, connected to the pad, and having a fourth metal layer and a fifth metal layer disposed between the fourth metal layer and the first insulating layer; and
a second via disposed in the second insulating layer, connected to the pad, and having a sixth metal layer and a seventh metal layer disposed between the sixth metal layer and the first insulating layer.

7. The semiconductor device according to claim 6,
wherein the second metal layer is also interposed between the pad and the first via.

8. The semiconductor device according to claim 1, further comprising:
in the first insulating layer,
a stacked body including a plurality of conductive layers stacked on top of one another with a distance between adjacent ones of the conductive layers; and
a pillar having a semiconductor layer that penetrates through the stacked body,
wherein the pillar is electrically connected to the pad.

9. The semiconductor device according to claim 8, further comprising:
a plurality of transistors disposed in the second insulating layer,
wherein the plurality of transistors are electrically connected to the pad.

10. A semiconductor device, comprising:
a first chip including a first insulating layer;
a second chip bonded to the first chip and including a second insulating layer;
a first pad provided around a first bonded surface of the first chip with the second chip; and
a second pad provided around a second bonded surface of the second chip with the first chip,
wherein the first and second pads each have a first metal layer including a first metal,
the first pad further includes a second metal layer disposed between the first metal layer and the first insulating layer,
the second pad further includes a third metal layer disposed between the first metal layer and the second insulating layer,
at least one of the second metal layer or the third metal layer include a second metal having oxidation energy lower than oxidation energy of the first metal, and
the first metal layer further includes the second metal.

11. The semiconductor device according to claim 10, wherein at least a portion of the second metal in the first metal layer is unevenly distributed at a crystal grain boundary of the first metal layer.

12. The semiconductor device according to claim 10, wherein the first metal is copper, and
the second metal includes at least one of titanium, manganese, aluminum, or magnesium.

13. The semiconductor device according to claim 12, wherein the second metal is contained in at least the second metal layer,
the second metal includes at least titanium, and
the second metal layer is a barrier metal layer.

14. The semiconductor device according to claim 12, wherein the second metal is contained in at least the second metal layer, and
the pad includes a barrier metal layer interposed between the second metal layer and the first insulating layer.

15. The semiconductor device according to claim 10, further comprising:
a first via disposed in the first insulating layer, connected to the pad, and having a fourth metal layer and a fifth metal layer disposed between the fourth metal layer and the first insulating layer; and
a second via disposed in the second insulating layer, connected to the pad, and having a sixth metal layer and a seventh metal layer disposed between the sixth metal layer and the first insulating layer.

16. The semiconductor device according to claim 15, wherein the second metal layer is also interposed between the pad and the first via.
